(19) United States
(12) Patent Application Publication
(10) Pub. No.: US 2005/0076947 A1
(43) Pub. Date: Apr. 14, 2005

(54) Sun followoing method in solar system

(76) Inventor: Hideo Kawata, Yorri-machi (JP)

Correspondence Address: Hideo Kawata, 1096-Yorii Yorii-machi Oosato-gun, Yorii-machi, 369-1203, JP

(21) Appl. No.: 10/766,669

(22) Filed: Jan. 29, 2004

(30) Foreign Application Priority Data
Jul. 5, 2001 (JP) 2001-005291
Jan. 31, 2002 (JP) 2002-62696
Jan. 22, 2003 (WO) PCT/JP03/00574

(51) Int. Cl. H01L 25/00

(52) U.S. Cl. 136/251

(57) ABSTRACT

1. The time of the sunrise 2. The time of the sunset 3. The time of the southing 4. The altitude in case of the southing (1) It understands a way of moving the day in the sun from 1, 2, 3, 4 above. (2) To decide the time to set and the position to set is made from (1) above. (3) The control board of “Solar-system Movable Mount” controls two mobiles of the turning-over part and the elastic part. It creates the agenda which controls the mobile of two pieces of the above based on the material which is (2). (4) The power of the control board uses the special solar cell of the control board. (5) When the above-mentioned solar cell doesn't generate electricity, the above-mentioned control board doesn't operate. Therefore, two mobiles of the above doesn't move.

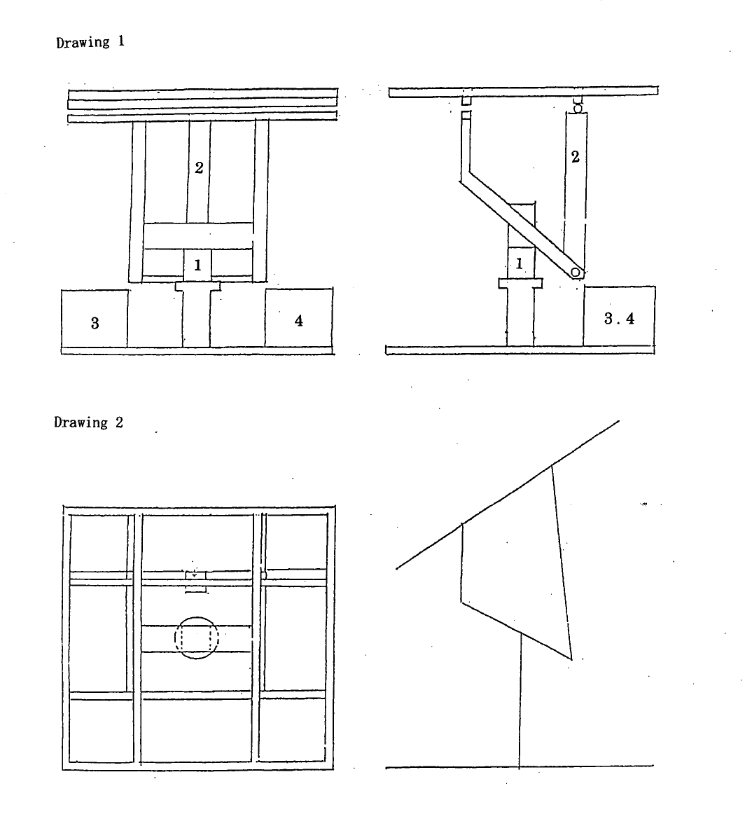

### BACKGROUND OF THE INVENTION

As for the amount of electric power generation of the solar cell, the pursuit type is bigger than the fixation type.

It thinks that the difference becomes by several times.

In that the above-mentioned stand uses the above-mentioned equipment, the amount of electric power generation of the solar cell becomes big.

To make a control system to the origin in this contrivance is important.

This contrivance can draw out the electric generating capacity of the solar cell to the most size.

“Jitugan 2001-005291 Solar-System Movable Mount” receives sunlight efficiently.

Then, it pursues the sun automatically.

### BRIEF SUMMARY OF THE INVENTION

“Solar-System Movable Mount” receives sunlight at the good angle of the efficiency to the power generation of the solar cell.

Then, “Solar-System Movable Mount” pursues the sun.

### DETAILED DESCRIPTION

“Jitugan 2001-005291 Solar-System Movable Mount” has two kinds of mobile parts of the turning-over part and the elastic part.

The turning-over part of the above-mentioned stand can correspond to the movement of the sun from the sunrise to the sunset.

The elastic part of the above-mentioned stand can react to the advanced change of the sun.

The above-mobile parts of the above-mount move at the set time.

Then, the above-mobile parts of the above-mount stop at the set position.

1. “Jitugan 2001-005291 Solar-System Movable Mount” has two kinds of mobile parts of the turning-over part and the elastic part.

2. The above-mobile parts of the “Jitugan 2001-005291 Solar-System Movable Mount” move at the set time .

3. Then, the above-mobile parts of the “Jitugan 2001-005291 Solar-System Movable Mount” stop at the set position.
